(19) United States
(12) Patent Application Publication
(10) Pub. No.: US 2026/0024720 A1
(43) Pub. Date: Jan. 22, 2026

(54) MULTI-CHARGED PARTICLE BEAM WRITING METHOD, MULTI-CHARGED PARTICLE BEAM WRITING APPARATUS, AND NON-TRANSITORY COMPUTER-READABLE STORAGE MEDIUM STORING A PROGRAM

(71) Applicant: NuFlare Technology, Inc., Yokohama-shi (JP)

(72) Inventor: Hiroshi MATSUMOTO, Yokohama-shi (JP)

(73) Assignee: NuFlare Technology, Inc., Yokohama-shi (JP)

(21) Appl. No.: 19/256,750

(22) Filed: Jul. 1, 2025

(30) Foreign Application Priority Data
Jul. 22, 2024 (JP) 2024-117145

(51) Int. Cl. H01J 37/317; H01J 37/302

(52) U.S. Cl. CPC H01J 37/3177; H01J 37/3026; H01J 2237/31764; H01J 2237/31769

(57) ABSTRACT

According to one aspect of the present invention, a multi-charged particle beam writing method includes setting, in a writing region on a target object, a plurality of writing grids in which relative positions of at least a portion of the plurality of writing grids are shifted from a plurality of ideal grids arranged at an even pitch in a gridded shape, and writing, using multiple beams, a pattern on the target object such that the plurality of writing grids in which the relative positions of the at least the portion of the plurality of writing grids are shifted are irradiated.

### CROSS-REFERENCE TO RELATED APPLICATION

This application is based upon and claims the benefit of priority from prior Japanese Patent Application No. 2024-117145 filed on Jul. 22, 2024 in Japan, the entire contents of which are incorporated herein by reference.

### BACKGROUND OF THE INVENTION

### Field of the Invention

Embodiments of the present invention relate to a multi-charged particle beam writing method, a multi-charged particle beam writing apparatus, and a non-transitory computer-readable storage medium storing a program thereon. For example, embodiments relate to a method for reproducing previous generation pattern writing by a multiple beam writing apparatus for an advanced process.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

In multiple beam writing, there is a case, for example, where a high-precision writing apparatus to be used for leading-edge process needs to write a pattern in precision obtained by a previous generation low-precision writing apparatus. Specifically, for example, there is a case where the same product as the one produced in the past needs to be created, or where it is sufficient for a final product semiconductor device to have the same performance as that of previous generation. As to masks, for example, in order to increase precision of a pattern shape formed on the mask, some countermeasures have been performed, such as adding an auxiliary pattern, etc. to an original pattern, or resizing the size of the pattern itself. These corrections as the countermeasures are called Mask Process Correction (MPC), and some of the corrections are performed taking a beam resolution of a writing apparatus into consideration. However, in a high-precision writing apparatus, with improvement of the writing precision and beam resolution, if a pattern is written employing writing data used in a previous generation writing apparatus, there is a possibility of not acquiring the same pattern shape as the one written by the previous generation writing apparatus. Meanwhile, it is desirable for mask manufacturing to obtain, in a high-precision writing apparatus, a writing result equivalent to that of a low-precision writing apparatus.

As a method for obtaining such a writing result described above, it can be thought, for example, to replace a part of the hardware of a high-precision writing apparatus with that of a low-precision writing apparatus. However, a problem exists in that coping completely is difficult when a plurality of low-precision specifications are needed. Therefore, it is desirable, with keeping the hardware of a high-precision writing apparatus, to write a pattern of precision obtained by a low-precision writing apparatus.

There is disclosed a technique, though which is not for adjusting the writing precision to the specification of a previous generation, for correcting distortion of multiple beams occurring on the surface of a target object by, using a projection optics, shifting the position of a hole in the aperture array, which forms multiple beams, from a regular position in multiple beam writing (e.g., refer to Japanese Patent Application Laid-open (JP-A) No. 2010-041055).

### BRIEF SUMMARY OF THE INVENTION

According to one aspect of the present invention, a multi-charged particle beam writing method includes
setting, in a writing region on a target object, a plurality of writing grids in which relative positions of at least a portion of the plurality of writing grids are shifted from a plurality of ideal grids arranged at an even pitch in a gridded shape, and
writing, using multiple beams, a pattern on the target object such that the plurality of writing grids in which the relative positions of the at least the portion of the plurality of writing grids are shifted are irradiated.

According to another aspect of the present invention, a multi-charged particle beam writing apparatus includes
a writing grid setting circuit configured to set, in a writing region on a target object, a plurality of writing grids in which relative positions of at least a portion of the plurality of writing grids are shifted from a plurality of ideal grids arranged at an even pitch in a gridded shape, and
a writing mechanism configured to write, using multiple beams, a pattern on the target object such that the plurality of writing grids in which the relative positions of the at least the portion of the plurality of writing grids are shifted are irradiated.

According to yet another aspect of the present invention, a non-transitory computer-readable storage medium storing a program for causing a computer to execute processing includes
setting, in a writing region on a target object, a plurality of writing grids in which relative positions of at least a portion of the plurality of writing grids are shifted from a plurality of ideal grids arranged at an even pitch in a gridded shape,
storing, in a storage device, the plurality of writing grids having been set, and
reading the plurality of writing grids from the storage device, and making a writing mechanism write, using multiple beams, a pattern on the target object such that the plurality of writing grids in which the relative positions of the at least the portion of the plurality of writing grids are shifted are irradiated.

### BRIEF DESCRIPTION OF THE DRAWINGS

FIG. 1 is an illustration showing a schematic diagram of a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram for explaining an example of a writing operation according to the first embodiment;

FIG. 5 is an illustration showing an example of an irradiation region of multiple beams and a writing target pixel according to the first embodiment;

FIG. 6 is an illustration showing an example of a position shift amount and a pattern edge formed in the case of shifting a writing grid to have an uneven pitch according to the first 15 embodiment;

FIG. 7 is an illustration showing an example of a dose distribution in the case of shifting a writing grid to have an uneven pitch according to the first embodiment;

FIG. 8 is an illustration showing an example of an effective dose distribution in the case of shifting a writing grid to have an uneven pitch according to the first embodiment;

FIG. 9 is an illustration showing an example of a writing grid pattern in the case of increasing a blur according to the first embodiment;

FIG. 10 is an illustration for explaining a total blur according to the first embodiment;

FIG. 11 is an illustration for explaining measurement of critical dimension uniformity and measurement of line edge roughness according to the first embodiment;

FIG. 12 is an illustration showing an example of a writing grid pattern that increases edge position roughness according to the first embodiment;

FIG. 13 is an illustration showing another example of a writing grid pattern that increases line edge roughness according to the first embodiment;

FIG. 14 is an illustration showing another example of a writing grid pattern that increases line edge roughness according to the first embodiment;

FIG. 15 is an illustration showing another example of a writing grid pattern that increases line edge roughness according to the first embodiment;

FIG. 16 is an illustration showing an example of a method of shifting a writing grid in the case of increasing the shift amount of a pattern mean position according to the first embodiment;

FIG. 17 is a flowchart showing an example of main steps of a writing method according to the first embodiment;

FIG. 18 is an illustration showing an example of a relationship between a dose latitude and a writing grid shift amount according to the first embodiment;

FIG. 19 is an illustration for explaining an example of a multiple beam writing operation according to the first embodiment;

FIG. 20 is an illustration showing an example of a pattern formed by writing according to the first embodiment;

FIG. 21 is an illustration showing an example of a pattern edge shape in the case of performing multiple writing according to the first embodiment;

FIG. 22 is an illustration showing another example of a pattern edge shape in the case of performing multiple writing according to the first embodiment; and

FIG. 23 is an illustration showing an example of a writing grid pattern in the case of degrading critical dimension uniformity among patterns according to the first embodiment.

### DETAILED DESCRIPTION OF THE INVENTION

Embodiments of the present invention provide a writing method and writing apparatus which can write, using a high-precision writing apparatus, a pattern of precision obtained by a low-precision writing apparatus, without replacing the hardware.

Embodiments of the present invention describe a configuration in which an electron beam is used as an example of a charged particle beam. The charged particle beam is not limited to the electron beam, and other charged particle beams such as an ion beam may also be used.

### First Embodiment

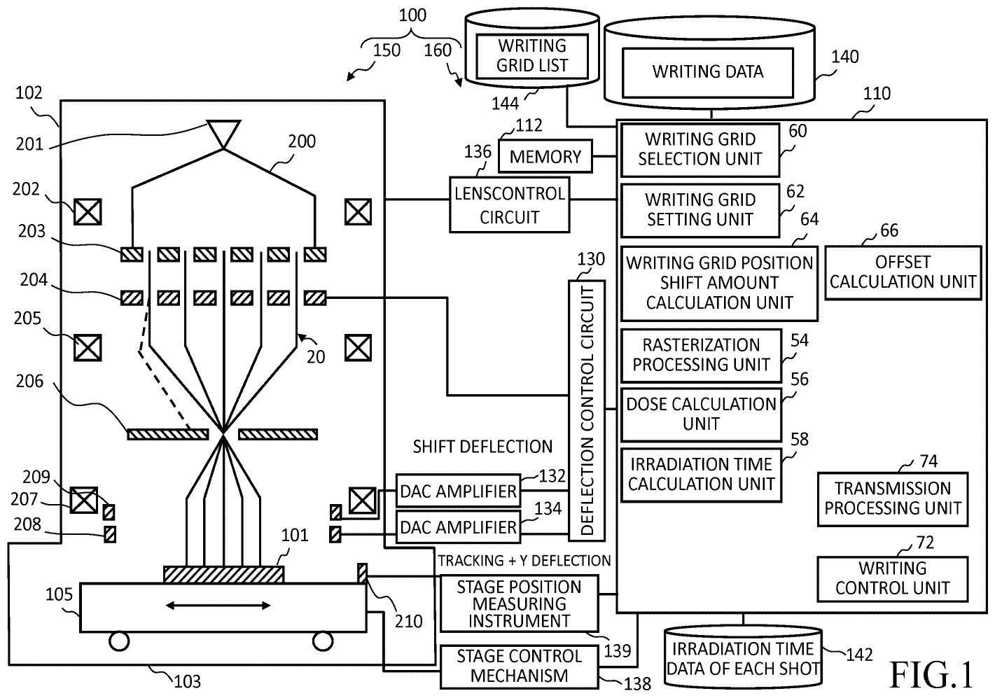

FIG. 1 is an illustration showing a schematic diagram of a configuration of a writing or “drawing” apparatus according to a first embodiment. As shown in FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a main deflector 208, and a sub deflector 209.

In the writing chamber 103, an XY stage 105 is disposed. On the XY stage 105, there is placed a target object or “sample” 101, such as a mask, serving as a writing target substrate when writing (exposure) is performed. For example, the target object 101 is an exposure mask used in fabricating semiconductor devices, or a semiconductor substrate (silicon wafer) for fabricating semiconductor devices. The target object 101 may be a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a stage control mechanism 138, a stage position measuring instrument 139, and storage devices 140, 142, and 144 such as magnetic disk drives. The control computer 110, the memory 112, the deflection control circuit 130, the lens control circuit 136, the stage control mechanism 138, the stage position measuring instrument 139, and the storage devices 140, 142, and 144 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Lenses, such as the illumination lens 202, the reducing lens 205, and the objective lens 207 are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a rasterization processing unit 54, a dose calculation unit 56, an irradiation time calculation unit 58, a writing grid selection unit 60, a writing grid setting unit 62, a writing grid position shift amount calculation unit 64, an offset calculation unit 66, a writing control unit 72, and a transmission processing unit 74. Each of the “ . . . units” such as the rasterization processing unit 54, the dose calculation unit 56, the irradiation time calculation unit 58, the writing grid selection unit 60, the writing grid setting unit 62, the writing grid position shift amount calculation unit 64, the offset calculation unit 66, the writing control unit 72, and the transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the rasterization processing unit 54, the dose calculation unit 56, the irradiation time calculation unit 58, the writing grid selection unit 60, the writing grid setting unit 62, the writing grid position shift amount calculation unit 64, the offset calculation unit 66, the writing control unit 72, and the transmission processing unit 74, and information being operated are stored in the memory 112 each time.

Writing operations of the writing apparatus 100 are controlled by the writing control unit 72. Processing of transmitting irradiation time data of each shot to the deflection control circuit 130 is controlled by the transmission processing unit 74.

Writing data (chip data) is input from the outside of the writing apparatus 100, and stored in the storage device 140. Chip data defines information on a plurality of figure patterns configuring a chip pattern. Specifically, for example, a figure code, coordinates, a size, and the like are defined for each figure pattern.

In the storage device 144, there is stored a writing grid list defining a plurality of writing grid patterns whose each position of the writing grid has been shifted by a preset reference shift amount ΔS.

FIG. 1 shows a configuration necessary for describing the first embodiment. Other configuration elements generally necessary for the writing apparatus 100 may also be included therein.

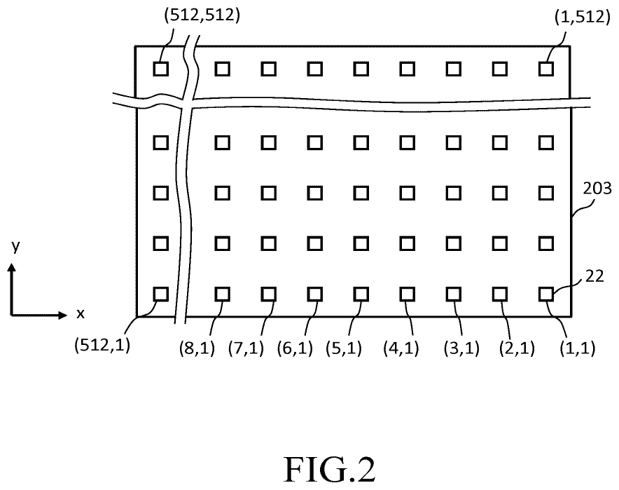

FIG. 2 is a conceptual diagram showing a configuration of a shaping aperture array substrate according to the first embodiment. As shown in FIG. 2, holes (openings) 22 of p columns wide (width in the x direction) and q rows long (length in the y direction) (p≥2, q>2) are formed, like a matrix, at a predetermined array pitch in the shaping aperture array substrate 203. In the case of FIG. 2, for example, holes 22 of 512×512, that is 512 holes in the x direction and 512 holes in the y direction, are formed. The number of the holes 22 is not limited thereto. For example, it is also preferable to form the holes 22 of 32×32. Each of the holes 22 is a rectangle (including square) having the same dimension and shape as each other. Alternatively, each of the holes 22 may be a circle with the same diameter as each other. The multiple beams 20 are formed by letting portions of an electron beam 200 individually pass through a corresponding one of a plurality of holes 22. In other words, the shaping aperture array substrate 203 forms the multiple beams 20. The shaping aperture array substrate 203 serves as an example of an emission source of the multiple beams 20 or an example of a multiple beam forming mechanism.

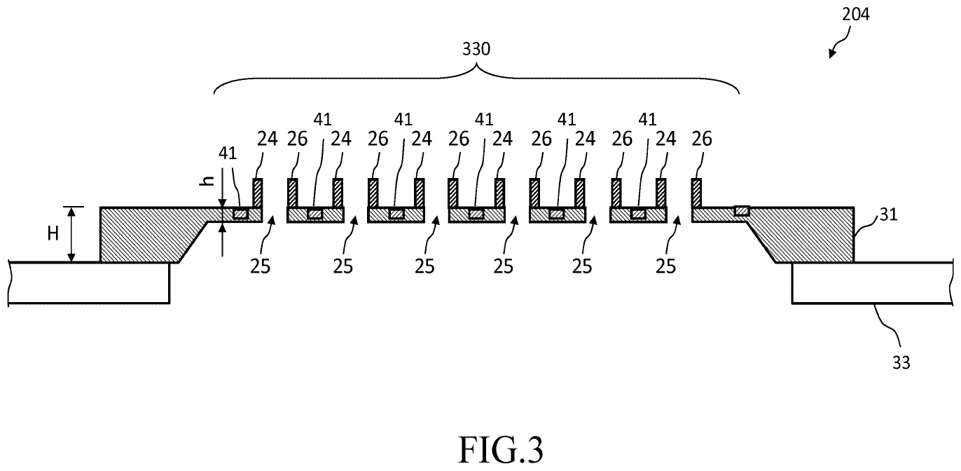

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam-off condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam-on condition by passing through the limiting aperture substrate 206. Blanking control is provided by such deflection.

Next, operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, each beam for one shot of the multiple beams 20 is formed by a beam which has been made during a period from becoming beam-on to becoming beam-off and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at a pitch obtained by multiplying the array pitch of a plurality of holes 22 in the shaping aperture array substrate 203 by the desired reduction ratio described above.

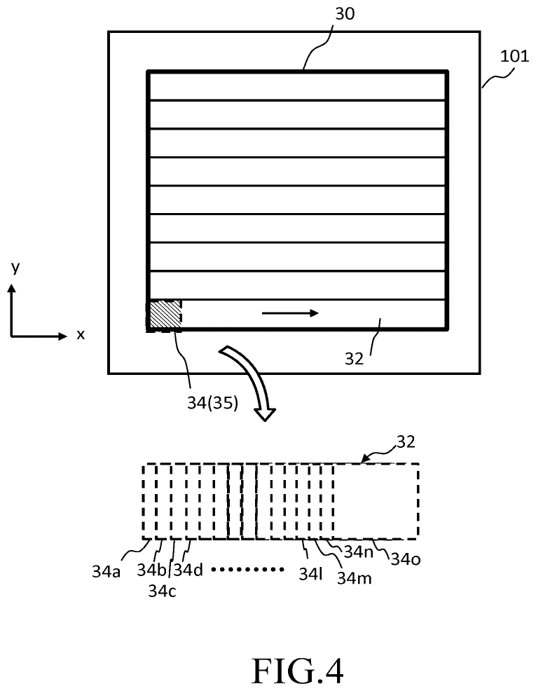

FIG. 4 is a conceptual diagram for explaining an example of a writing operation according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple beams 20. The x-direction design size of the irradiation region 34 of the multiple beams 20 can be defined by (the number of x-direction beams)×(x-direction beam pitch). The y-direction size of the rectangular irradiation region 34 can be defined by (the number of y-direction beams)×(y-direction beam pitch).

First, the XY stage 105 is moved to make an adjustment such that the irradiation region 34 of the multiple beams 20 is located at the left end, or at a position further left than the left end, of the first stripe region 32, and then writing of the first stripe region 32 is performed. When writing the first stripe region 32, the XY stage 105 is moved, for example, in the −x direction, so that the writing may proceed relatively in the x direction. The XY stage 105 is moved, for example, continuously at a constant speed. After writing the first stripe region 32, the stage position is moved in the −y direction by the width of the stripe region 32.

Next, an adjustment is made so that the irradiation region 34 of the multiple beams 20 can be located at the left end, or at a position further left than the left end, of the second stripe region 32. Then, writing of the second stripe region 32 is performed by moving the XY stage 105, for example, in the −x direction to proceed the writing relatively in the x direction.

FIG. 4 shows the case where respective stripe regions 32 are written in the same direction, but, it is not limited thereto. For example, with respect to the stripe region 32 to be written following the stripe region 32 having been written in the x direction, it may be written in the −x direction by moving the XY stage 105 in the x direction, for example. Thus, due to performing writing while alternately changing the writing direction, the stage moving time can be reduced, which results in reducing the writing time. Owing to one shot of multiple beams 20 having been formed by individually passing through the holes 22 in the shaping aperture array substrate 203, a plurality of shot patterns up to the number of the holes 22 are maximally formed at a time.

Although FIG. 4 shows the case where the stage moving for writing each stripe region is performed once for each writing, it is not limited thereto. It is also preferable to perform multiple writing (multiple pass writing) such that the stage moves on the same position a plurality of times. In that case, preferably, the multiple writing is performed while shifting the position in the y direction by 1/n of the width of the stripe region. Alternatively, it is also preferable to perform multiple writing (multiple writing in a pass) that writes the same position plural times by different beams during one stage movement.

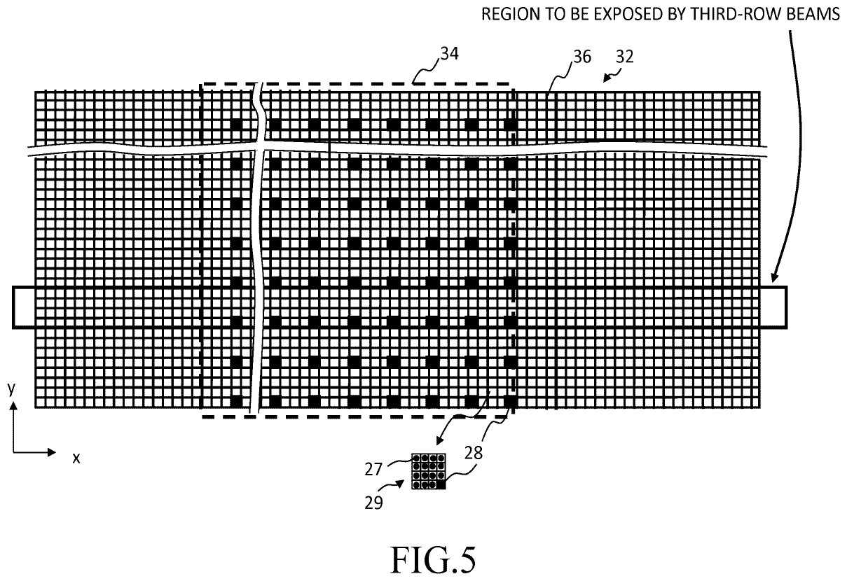

FIG. 5 is an illustration showing an example of an irradiation region of multiple beams and a pixel to be written (writing target pixel) according to the first embodiment. In FIG. 5, the stripe region 32 is divided into a plurality of mesh regions by the beam size of each of the multiple beams 20, for example. Each mesh region serves as a writing target pixel 36 (unit region of beam irradiation, irradiation position). The size of the writing target pixel 36 is not limited to the beam size, and may be any size regardless of beam size. For example, it may be 1/n (n being an integer of 1 or more) of the beam size. FIG. 5 shows the case where the writing region on the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the rectangular, including square, irradiation region 34 can be defined by (the number of x-direction beams)×(x-direction beam pitch). The y-direction size of the rectangular irradiation region 34 can be defined by (the number of y-direction beams)×(y-direction beam pitch). FIG. 5 shows the case of multiple beams of 512×512 (rows×columns) having been simplified to 8×8 (rows×columns). In the irradiation region 34, there are shown a plurality of pixels 28 (beam writing positions) which can be irradiated with one shot of the multiple beams 20. The pitch between adjacent pixels 28 is the beam pitch of the multiple beams. A sub-irradiation region 29 (pitch cell region) is configured by a rectangular, including square, region surrounded by the size of beam pitches in the x and y directions. In the example of FIG. 5, each sub-irradiation region 29 is composed of 4×4 pixels, for example.

Furthermore, each pixel 36 is configured centering on each writing grid 27. Ideally, each writing grid 27 is coincident with one of a plurality of ideal grids, being different from each other, arranged at an even pitch on a plurality of straight lines in a gridded shape. For example, each writing grid 27 is coincident with one of a plurality of ideal grids, being different from each other, arranged at an even pitch at intersections of a plurality of straight lines in a gridded shape.

As described above, in multiple beam writing, there is a case, for example, where a high-precision current generation writing apparatus, to be used for leading-edge process, needs to write a pattern in precision obtained by a low-precision previous generation writing apparatus. However, with improvement of the writing precision, if a high-precision writing apparatus writes a pattern by employing writing data used in a previous generation writing apparatus, there is a possibility of not actually obtaining a desired pattern shape. Therefore, it is desirable, in a high-precision writing apparatus, to obtain a writing result equivalent to that of a low-precision writing apparatus.

Then, according to the first embodiment, a high-precision writing apparatus writes a pattern in precision equivalent to that of a low-precision writing apparatus by purposefully increasing a blur in the dose distribution occurring at the irradiation position of an electron beam on the target object 101, increasing a line edge roughness (LER), and/or increasing the shift amount of a pattern mean position. It will be specifically described.

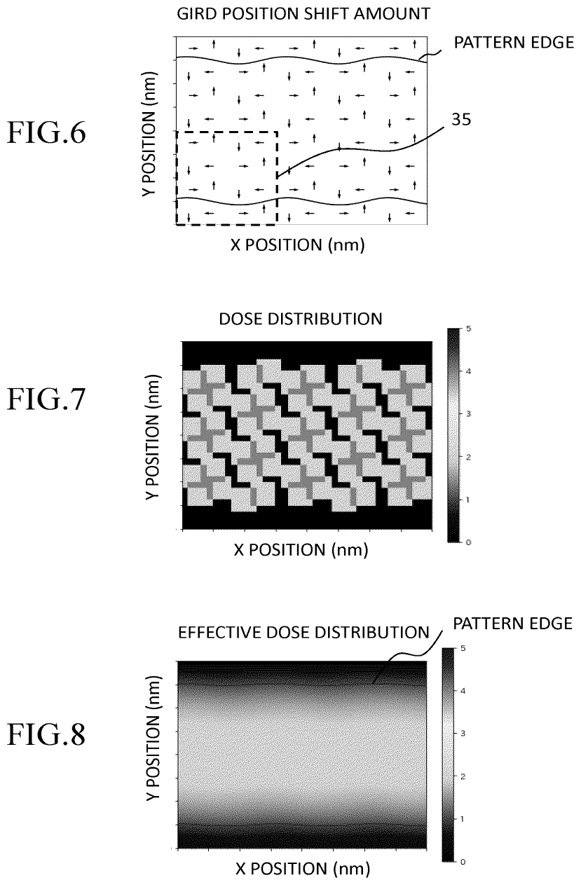

FIG. 6 is an illustration showing an example of a position shift amount and a pattern edge formed in the case of shifting a writing grid to have an uneven pitch according to the first embodiment.

FIG. 7 is an illustration showing an example of a dose distribution in the case of shifting a writing grid to have an uneven pitch according to the first embodiment.

FIG. 8 is an illustration showing an example of an effective dose distribution in the case of shifting a writing grid to have an uneven pitch according to the first embodiment.

FIG. 6 shows a portion of a writing region in the case of making the beam pitch four times the beam size, and making an interval between exposure grids the same as the beam size. Therefore, a rectangular region 35 which has the height and the width each being the same as a beam pitch is composed of 4×4 pixels. The positions of four writing grids aligned in the x direction in the first row of the rows being aligned in the y direction in each rectangular region 35 are individually shifted from the ideal grid by the reference shift amount ΔS, in order from the left, in the −y direction, −x direction, +x direction, and +y direction. The positions of four writing grids aligned in the x direction in each of the second, third, and fourth rows aligned in the y direction in each rectangular region 35 are also individually shifted from the ideal grid. In this process, the position shift direction and the position shift amount are set such that the sum of vectors each representing a position shift amount in each column is zero, and the sum of vectors each representing a position shift amount in each row is zero. At this time, the vector which indicates the position shift amount of each beam pitch is the same as each other. Then, by applying beams to each writing grid on the position shifted from the ideal grid position as described above, the dose distribution shown in FIG. 7 is acquired. Assuming that the total blur of the beam blur and the resist blur has the same size as the beam size, if a distribution function indicating the total blur, and the dose distribution in FIG. 7 are convolved, the effective dose close to the pattern edge becomes non-uniform as shown in FIG. 8. Thus, it turns out that it is possible to make the pattern edge wavy not straight as shown in FIG. 6.

Using this phenomenon, according to the first embodiment, increasing a blur in the dose distribution occurring at the irradiation position on the target object 101 of an electron beam, increasing a line edge roughness (LER), or increasing the shift amount of a pattern mean position can be realized by purposefully shifting (offset) the position of a writing grid from the position of an ideal grid. The pattern of combination of the shift amount (offset) and the shift direction of a writing grid from an ideal grid is changed depending on a desired one of the increase in blur, the increase in line edge roughness (LER) and the increase in the shift amount of a pattern mean position. The increase in blur, the increase in line edge roughness (LER), and the increase in the deviation of the average pattern position, in this order, correspond to the cycle of a position shift distribution of a writing grid, in order, from a short cycle case to a long cycle case. There is a case where the above two effects seem to be mixed depending on the cycle of the position shift distribution.

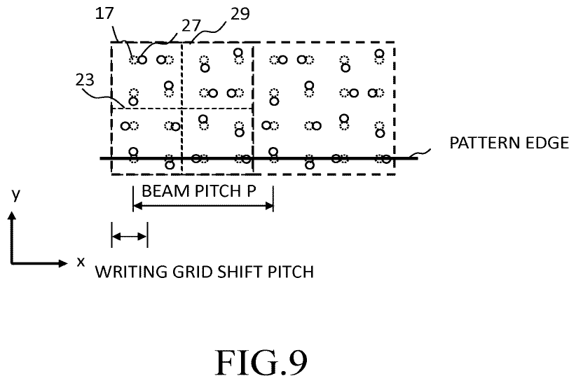

FIG. 9 is an illustration showing an example of a writing grid pattern in the case of increasing a blur according to the first embodiment. In the example of FIG. 9, in each sub-irradiation region 29 in the stripe region 32, the position of each writing grid 27 is shifted from the position of an ideal grid 17. FIG. 9 shows the case where each sub-irradiation region 29 is composed of 4×4 writing grids 27 (or pixels).

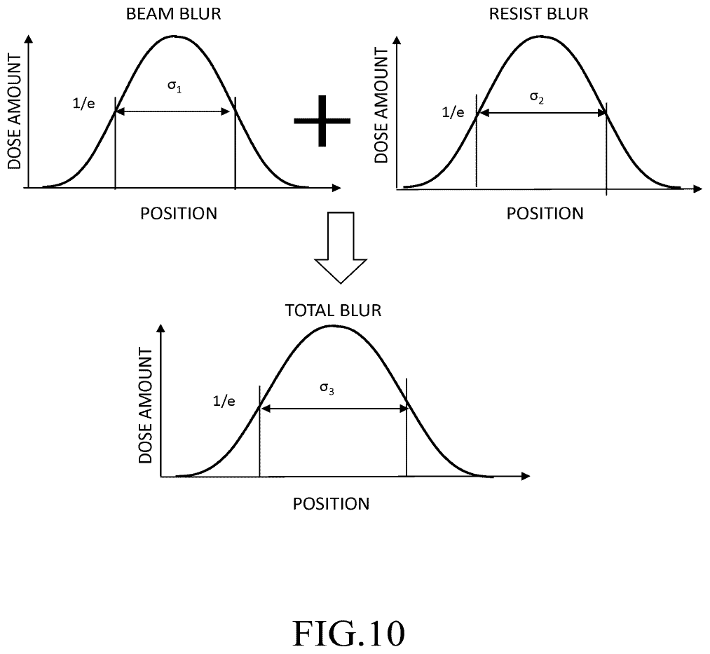

FIG. 10 is an illustration for explaining a total blur according to the first embodiment. In an electron beam, in addition to a blur (beam blur) indicating a spread of the electron beam resulting from an optical system, there occurs another blur (resist blur), at the development stage, indicating a spread of the electron beam by acid diffusion from the resist irradiated with beams. By using a standard deviation σ₁ of a beam blur distribution function and a standard deviation σ₂ of a resist blur distribution function, a distribution function g(x) of a total blur can be defined using, for example, a Gaussian distribution function by the equation (1-1) described below. A standard deviation σ₃ of a total blur distribution function can be defined by the equation (1-2) described below.

$$g ( x ) = {e}^{- \frac{{x}^{2}}{{σ}_{3}^{2}}} \qquad ( 1 - 1 )$$

$${σ}_{3} = \sqrt{{σ}_{1}^{2} + {σ}_{2}^{2}} \qquad ( 1 - 2 )$$

A dose distribution d′(x) after development at the irradiation position of the target object 101 can be defined by the equation (2) described below using an incident dose (x).

$${d}^{′} ( x ) = \int d ( x - {x}^{′} ) g ( {x}^{′} ) {dx}^{′} \qquad ( 2 )$$

In the case of increasing a blur, the pitch (or “cycle”) of shifting (position shift) the writing grid 27 is set to be less than the standard deviation σ₃ of the total blur distribution function. Generally, the standard deviation σ₃ of the total blur distribution function is larger than the beam size. For example, in the case of the beam size being 20 nm, σ₃ is from 20 to 30 nm. In the example of FIG. 9, the writing grid 27 is shifted by a pitch equal to or less than the array pitch of the writing grid 27, for example. In other words, shifting is performed for each writing grid 27. A writing grid pattern is set such that the sum of vectors each of which represents a position shift amount from a local ideal grid 17 in the sub-irradiation region 29, namely, for example, a position shift amount from the ideal grid 17 in the writing grids 27 in a sub-pitch cell 23 is zero. In the example of FIG. 9, a plurality of writing grids 27 are set such that the average of position shift amounts of the writing grids 27 in each of a plurality of sub-pitch cells 23 (sub-regions) obtained by dividing the sub-irradiation region 29, on the surface of the target object 101, surrounded to be a quadrangle by the beam pitch size of the multiple beams 20 is zero. FIG. 9 shows the case where the sub-irradiation region 29 is composed of 4×4 writing grids (or pixels), and the sub-pitch cell 23 is composed of 2×2 writing grids (or pixels). In each sub-pitch cell 23, the positions of 2×2 writing grids are shifted from the ideal grid by the same position shift amount in +x, −x, +y, and −y directions. By making the sum of vectors each representing a position shift amount from the local ideal grid 17 in the sub-irradiation region 29 zero, it is possible to inhibit degradation of critical dimension uniformity (CDU) due to shifting a writing grid.

Furthermore, the position shift direction and the position shift amount are set such that the sum of vectors, each representing a position shift amount from the ideal grid 17, in each column of the writing grids 27 in each sub-irradiation region 29 is zero, and the sum of vectors, each representing a position shift amount from the ideal grid 17, in each row of the writing grids 27 is zero. By this, degradation of line edge roughness (LER) can be inhibited. It is not inevitably necessary that the sum of vectors each of which represents a position shift amount is zero, and thus, the same effect can be obtained when the sum is a fixed value.

The writing grid pattern of each sub-irradiation region 29 is set to be the same. Thereby, for each shot of the multiple beams 20, each writing grid 27 to be irradiated has the same shift direction and the same shift amount, and therefore, shifting can be performed by collective deflection of the multiple beams 20.

By making the pitch of shifting (position shifting) the writing grid 27 smaller than the standard deviation σ₃ of the total blur distribution function, it is possible to increase a blur without changing the shape of a pattern edge.

Although, in the example described above, the shift pitch of the writing grid is set to be one writing grid, it is not limited thereto. For example, in the case where the beam size is 20 nm, and the standard deviation σ₃ of the total blur distribution function is 80 nm, the shift pitch may be set to two or three writing grids. If the pitch of shifting (position shifting) the writing grid is made smaller than 03, the shift of the writing grid is within a total blur, and therefore, since the shift amount is hidden in a blur, the blur can be increased without changing the shape of the pattern edge.

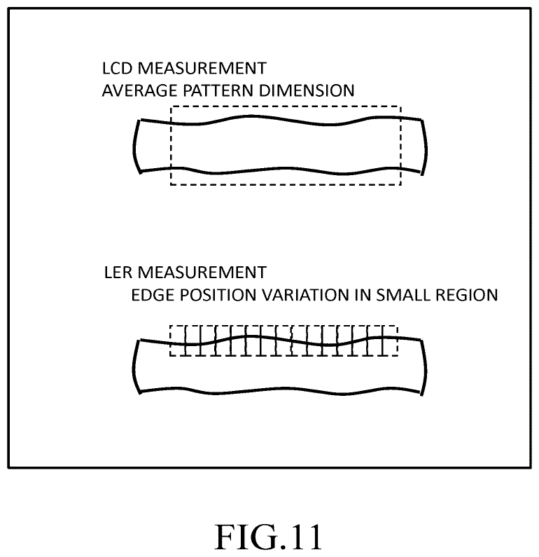

FIG. 11 is an illustration for explaining measurement of critical dimension uniformity (CDU) and measurement of line edge roughness (LER) according to the first embodiment. In measuring a line critical dimension (LCD), an average critical dimension of a pattern in a region having a length of around 1 μm is measured, for example. In contrast, in measuring a line edge roughness (LER), variation of a pattern edge position in a region sufficiently smaller than the region for CDU measurement is measured.

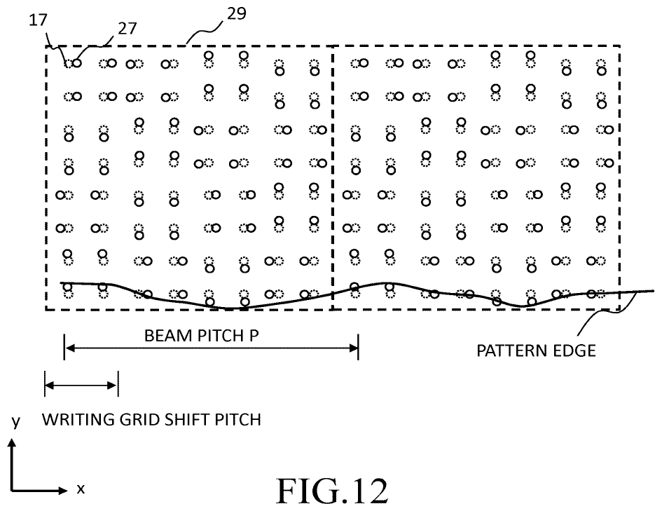

FIG. 12 is an illustration showing an example of a writing grid pattern that increases edge position roughness according to the first embodiment. FIG. 12 shows the case where each sub-irradiation region 29 is composed of 8×8 writing grids 27 (or pixels).

In the case of increasing line edge roughness (LER), the pitch of shifting (position shifting) the writing grid 27 is set to be comparable to or a little larger than the standard deviation σ₃ of the total blur distribution function. For example, if the interval between the writing grids is 20 nm and σ₃ is 20 to 30 nm, the writing grid 27 is shifted by the pitch of two writing grids 27 in the case of FIG. 12. Here, a plurality of writing grids 27 are set such that the sum of vectors in each column and the sum of vectors in each row are individually zero, where each vector represents a position shift amount of each of the writing grids 27 in the sub-irradiation region 29, on the surface of the target object 101, surrounded to be a quadrangle by the beam pitch size of the multiple beams 20. In each sub-irradiation region 29, shifting is performed for every two writing grids in each column to be shifted from the ideal grid 17 by the same position shift amount in +x, −x, +y, and −y directions. Similarly, in each row, shifting is performed for every two writing grids to be shifted from the ideal grid 17 by the same position shift amount in +x, −x, +y, and −y directions. It is not inevitably necessary that the sum of vectors each of which represents a position shift amount is zero, and thus, the same effect can be obtained when the sum is a fixed value.

The writing grid pattern of each sub-irradiation region 29 is set to be the same as each other. Thereby, for each shot of the multiple beams 20, each writing grid 27 to be irradiated has the same shift direction and the same shift amount, and therefore, shifting can be performed by collective deflection of the multiple beams 20.

By setting the pitch of shifting (position shifting) the writing grid 27 to be comparable or a little larger than the standard deviation σ₃ of the total blur distribution function, the shift effect is not canceled out by the total blurring, and thus, the pattern edge can be changed from straight to gently wavy. Consequently, LER can be increased. Meanwhile, since the average value in the region for CDU measurement is a value close to zero, it is possible to prevent that the shift effect affects the CDU.

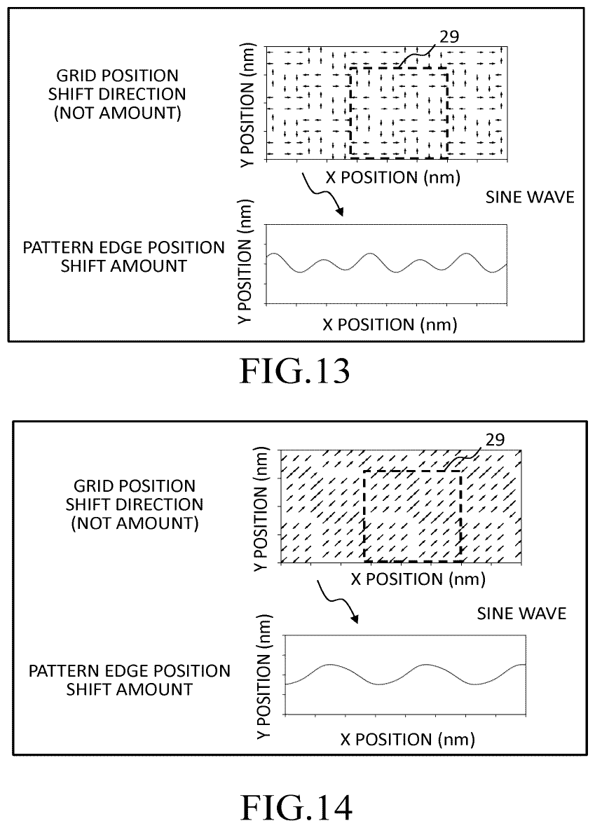

FIG. 13 is an illustration showing another example of a writing grid pattern that increases line edge roughness according to the first embodiment.

FIG. 14 is an illustration showing another example of a writing grid pattern that increases line edge roughness according to the first embodiment.

FIG. 13 shows the case where writing grids in, for example, the first row in the sub-irradiation region 29 are shifted by two writing grids in −x, +x, +y, and −y directions in order. FIG. 14 shows the case where writing grids in, for example, the first row in the sub-irradiation region 29 are shifted by four writing grids in the oblique −x, the oblique −y, the oblique +x, and the oblique +y directions in order. Thus, by changing the shift pitch from two writing grids to four writing grids, the cycle of the gentle curve of a pattern edge can be doubled. Therefore, it turns out that the cycle of the curve wave of a pattern edge can be controlled by adjusting the shift pitch.

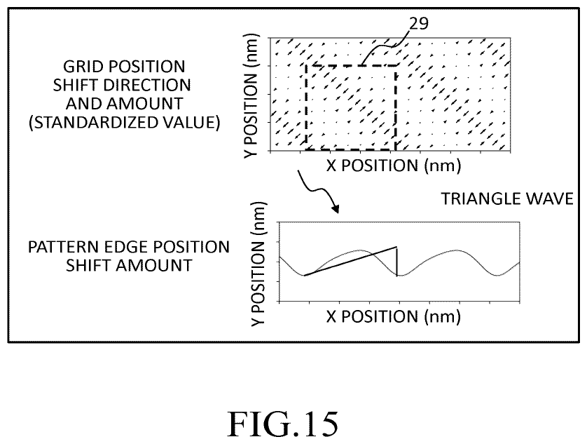

FIG. 15 is an illustration showing another example of a writing grid pattern that increases line edge roughness according to the first embodiment. FIG. 15 shows, for example, the case where the writing grids in the first row in the sub-irradiation region 29 are shifted by four writing grids in the oblique −x, the oblique −y, the +x, and the oblique +y directions in order. In the example of FIG. 15, shift amounts in the oblique −x and the oblique −y directions of the four writing grids are made to gradually decrease, and shift amounts in the oblique +x and the oblique +y directions of the four writing grids are made to gradually increase. In FIG. 14, the pattern edge of the four writing grids having the same shift pitch is a sine wave curve. On the other hand, in FIG. 15, the pattern edge is a triangular wave curve. Accordingly, the shape of the pattern edge curve can be varied by changing the shift amount in the shift pitch of the writing grid.

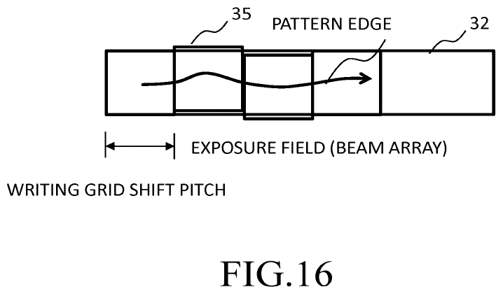

FIG. 16 is an illustration showing an example of a method of shifting a writing grid in the case of increasing the shift amount of a pattern mean position according to the first embodiment. When increasing the shift amount of the mean position of a pattern, the pitch of shifting (position shift) the writing grid 27 is set to be equal to or greater than a beam array size. A plurality of writing grids in which relative positions of at least a portion of the plurality of writing grids are shifted are set by providing a position shift amount to at least a portion of the plurality of ideal grids. In the example of FIG. 16, for each rectangular region 35 of the same size as a beam array, the position of each writing grid 27 is shifted from the position of the ideal grid 17. It is preferable that the rectangular region 35 is defined to be the same size as the irradiation region 34. In multiple beam writing, as shown in FIG. 4, the stripe region 32 is written due to the irradiation region 34 gradually proceeding in the writing direction. In this process, a tracking operation is repeated as described below. If, for example, ten times tracking operations are needed to apply shots to all the pixels 36 in one rectangular region 35, the writing grid 27 is shifted every ten times tracking operations. For example, it is repeated as follows: in the 1st to 10th tracking operations, the shift amount of the writing grid 27 is zero, in the 11th to 20th tracking operations, the shift amount in the +y direction of the writing grid 27 from the ideal grid 17 is 5 nm, in the 21st to 30th tracking operations, the shift amount in the −y direction of the writing grid 27 from the ideal grid 17 is 5 nm, and in the 31st to 40th tracking operations, the shift amount of the writing grid 27 from the ideal grid 17 is zero, . . . and so on. Thereby, the pattern positon can be gradually shifted per tens of μm, for example.

As described above, by changing, in accordance with a purpose, the pitch of a shift (position shift) of the writing grid 27, it is possible to increase a blur in a dose distribution occurring at the irradiation position of an electron beam on the target object 101, increase a line edge roughness (LER), or increase a shift amount of a pattern mean position. Furthermore, two or three of them may be simultaneously performed. In that case, writing is performed employing a shift amount which is added by a shift amount corresponding to each purpose.

Specific operations are described below.

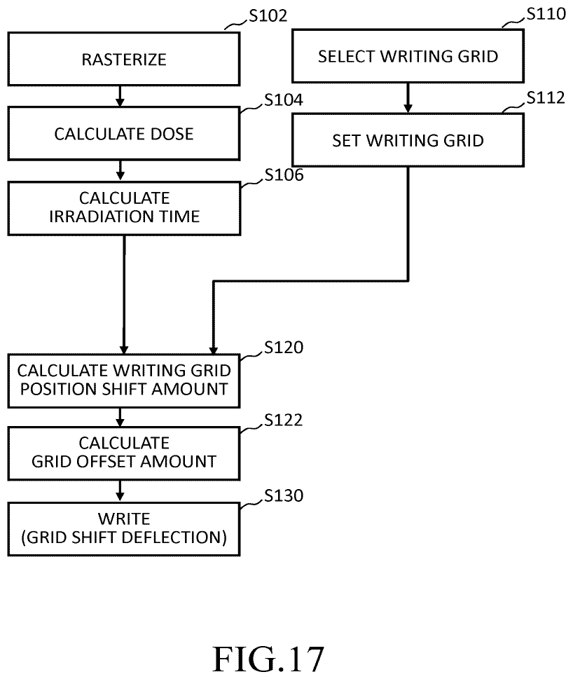

FIG. 17 is a flowchart showing an example of main steps of a writing method according to the first embodiment. In FIG. 17, the writing method of the first embodiment executes a series of steps: a rasterization processing step (S102), a dose calculation step (S104), an irradiation time calculation step (S106), a writing grid selection step (S110), a writing grid setting step (S112), a writing grid position shift amount calculation step (S120), a grid offset amount calculation step (S122), and a writing (grid shift deflection) step (S130).

In the rasterization processing step (S102), the rasterization processing unit 54 performs, in a plurality of ideal grids 17, rasterization on pattern data to be written. In other words, the rasterization processing unit 54 reads chip pattern data (writing data) from the storage device 140, and performs rasterization processing. Specifically, pattern density p (pattern area density) is calculated for each pixel 36 of the ideal grid 17.

In the dose calculation step (S104), the dose calculation unit 56 first calculates, for each proximity mesh region, a proximity effect correction dose Dp(x) for correcting a proximity effect. An unknown proximity effect correction dose Dp(x) can be defined by a threshold value model for proximity effect correction, which is the same as the one used in a conventional method, where a backscatter coefficient n, a dose threshold value Dth of a threshold value model, a pattern area density ρ″, and a distribution function f(x) are used. The proximity effect correction dose Dp(x) can be obtained as a relative value standardized by defining the base dose D_{base} to be 1. The size of the proximity mesh region is preferably set to be about 1/10 of the influence range of the proximity effect, such as about 1 μm.

Next, the dose calculation unit 56 calculates, for each pixel 36 of the ideal grid 17, an incident dose d(x) (amount of dose) with which the pixel 36 concerned is irradiated. The incident dose d(x) can be calculated, for example, by multiplying a base dose D_{base} by a proximity effect correction dose Dp and a pattern area density ρ. The base dose D_{base} can be defined by Dth/(1/2+η), for example. Thereby, it is possible to obtain an incident dose d(x), for which a proximity effect has been corrected, based on a layout of a plurality of figure patterns defined by the writing data. Alternatively, it is also preferable that the dose calculation unit 56 defines an incident dose d(x) for each pixel by using an incident dose d(x) standardized by regarding the base dose D_{base} as 1. In that case, for example, the incident dose d(x) can be calculated by multiplying the proximity effect correction dose Dp and the pattern area density ρ.

Next, the dose calculation unit 56 generates a dose map whose element is an incident dose d(x) of each pixel 36. In other words, each pixel (position) (x, y) and its incident dose d(x) are relatedly defined. The generated dose map is stored in the storage device 142. The dose calculation unit 56 generates a dose map with respect to the whole of the writing region 30 where writing processing is performed in accordance with the writing data (chip data).

In the case of performing multiple writing, a dose map is generated for each writing processing of each time of multiple writing.

In the irradiation time calculation step (S106), the irradiation time calculation unit 58 calculates an irradiation time “t” for each pixel 36 by using an incident dose d(x) (amount of dose). The irradiation time “t” for each pixel 36 can be calculated by dividing the incident dose d(x) of a pixel concerned by a current density J. In the case of the incident dose d(x) defined in the dose map is standardized by regarding the base dose D_{base} as 1, the irradiation time “t” of each pixel 36 can be calculated by dividing, by the current density J, the value obtained by multiplying the incident dose d(x) by the base dose D_{base}.

The writing control unit 72 rearranges obtained irradiation time data for each pixel 36 in the order of shots, and stores it in the storage device 142. The transmission processing unit 74 transmits the irradiation time data to the deflection control circuit 130 in the order of shots.

In the writing grid selection step (S110), referring to a writing grid list stored in the storage device 144, the writing grid selection unit 60 selects, in order to acquire a target effect, a writing grid pattern in a plurality of writing grid patterns. In the case of increasing a blur, a writing grid pattern whose pitch of shifting (position shift) the writing grid 27 has been set to be less than the standard deviation σ₃ of the total blur distribution function is selected. In the case of increasing LER, a writing grid pattern whose pitch of shifting (position shifting) the writing grid 27 has been set to be comparable to σ₃ is selected. In the case of increasing a shift amount of a pattern mean position, a writing grid pattern whose pitch of shifting (position shift) the writing grid 27 has been set to be equal to or greater than a beam array size is selected. The standard deviation σ₃ of the total blur distribution function is measured in advance by an experiment or simulation.

In the writing grid setting step (S112), the writing grid setting unit 62 sets, in a writing region on the target object 101, a plurality of writing grids 27 in which relative positions of at least a portion of the grids are shifted from a plurality of ideal grids 17 arranged at an even pitch in a gridded shape. For example, the writing grid setting unit 62 sets, in the stripe region 32 (writing region) on the target object 101, a plurality of writing grids 27 whose positions are shifted at a predetermined pitch in a writing direction (x direction) from a plurality of ideal grids 17 arranged at an even pitch on a plurality of straight lines in a grid shape. Here, the shift amount (position shift amount) of each writing grid of a selected writing grid pattern is changed depending on a blur, LER, and/or a shift amount of a pattern mean position which are obtained in a previous generation writing apparatus. Since the shift amount of a selected writing grid pattern is a standard shift amount ΔS, the shift amount can be made greater or smaller to be matched with performance obtained in a previous generation writing apparatus, by multiplying by the coefficient “k”. In order to acquire a plurality of effects, a writing grid pattern added by a writing grid pattern corresponding to each effect and its coefficient is generated to be set.

With respect to LER and/or a shift amount of a pattern mean position, the amplitude of the curve of an acquired pattern edge can be increased by increasing a shift amount of a writing grid.

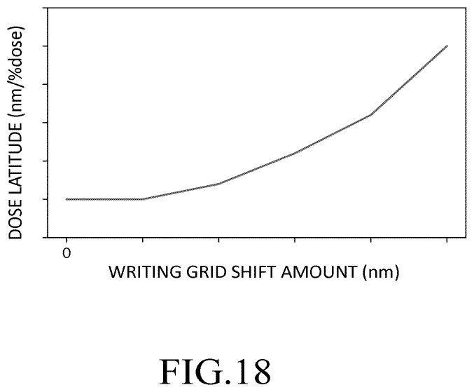

FIG. 18 is an illustration showing an example of a relationship between a dose latitude and a writing grid shift amount according to the first embodiment. In FIG. 18, the ordinate axis represents a dose latitude (nm/% dose), and the abscissa axis represents a shift amount (nm) of a writing grid. The dose latitude indicates the change amount of a pattern line width per unit dose. As shown in FIG. 18, it turns out that the larger the writing grid shift amount becomes, the higher the dose latitude becomes. Since the rise of the dose distribution becomes gentler along with the blur becoming larger, the change amount of a pattern line width per unit dose becomes larger. In other words, the larger the blur becomes, the higher the dose latitude becomes. Therefore, similarly to LER and the shift amount of the pattern mean position, the increase amount of a blur can also be increased by incrementing the shift amount of a writing grid.

Information on each writing grid having been set is stored in the storage device 142.

In the writing grid position shift amount calculation step (S120), the writing grid position shift amount calculation unit 64 reads information on a plurality of writing grids from the storage device 142, and calculates a position shift amount of each writing grid 27 in the stripe region 32. The writing grid position shift amount calculation unit 64 generates a position shift map whose element is a position shift amount of each writing grid, and stores it in the storage device 142.

In the grid offset amount calculation step (S122), the offset calculation unit 66 calculates, for each shot of the multiple beams 20, an offset direction and an offset amount of the writing grid 27. As described above, for each sub-irradiation region 29, each of the writing grids 27 having the same positional relationship as each other is set to have the same shift direction and the same shift amount. Therefore, for each shot, the multiple beams 20 can be collectively deflected by a calculated offset amount in a calculated offset direction.

When starting performing the following writing step, in addition to controlling using a position shift map, it is also preferable to control using a deflection shift amount map generated by adding a grid offset amount to a sub deflection shift amount of the sub deflector 209 used in changing, for each shot, an irradiation target pixel, or to a main deflection shift amount of the main deflector 208 used at each tracking cycle.

In the writing (grid shift deflection) step (S130), under the control of the writing control unit 72, the writing mechanism 150 writes, using the multiple beams 20, a pattern on the target object 101 so that a plurality of writing grids 27 in which relative positions of at least a portion of the grids are shifted may be irradiated. In this process, the writing mechanism 150 applies the multiple beams 20 to a plurality of writing grids 27 whose positions have been shifted with a beam of an incident dose d(x) for each ideal grid 17, based on data rasterized in a plurality of ideal grids 17. Furthermore, for each shot, the sub deflector 209 deflects the multiple beams 20, based on a shift amount (position shift amount) of a grid. Thereby, the position shifted by a grid shift amount from the ideal grid 17 defined in each writing grid 27 is irradiated with a beam for the writing grid concerned.

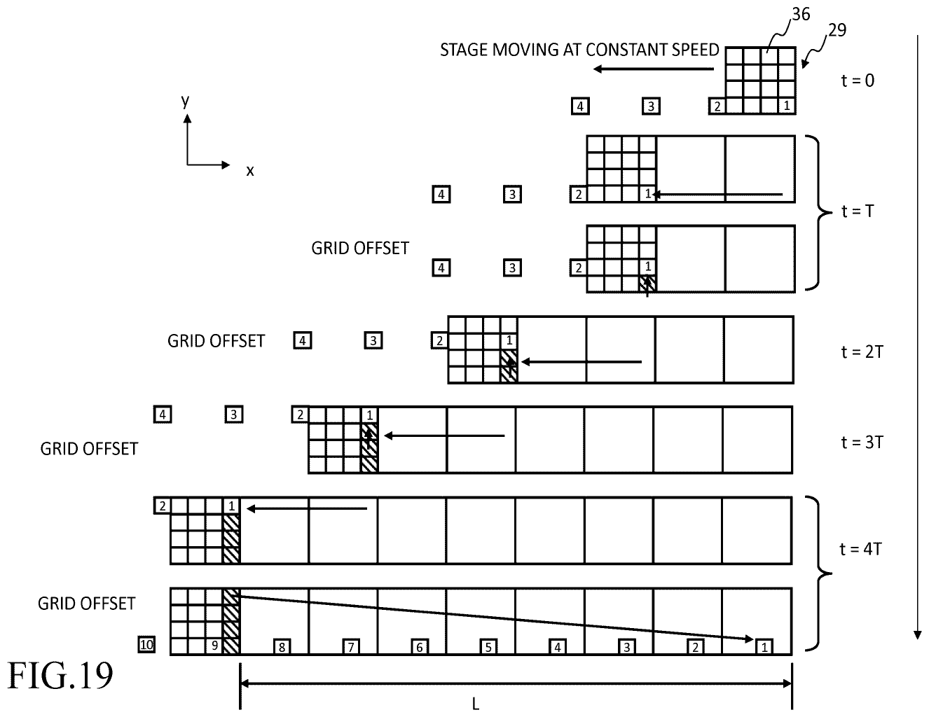

FIG. 19 is an illustration for explaining an example of a multiple beam writing operation according to the first embodiment. FIG. 19 shows the case where the inside of each sub-irradiation region 29, which includes the beam irradiation position of one of the multiple beams 20 and is surrounded by the beam pitch (pitch between beams), is written with four different beams. The example of FIG. 19 shows a writing operation where the XY stage 105 continuously moves at the speed at which the XY stage 105 moves the distance of eight beam pitches while writing a ¼ region, namely the region of 1/(the number of beams used for irradiation), in each sub-irradiation region 29. FIG. 19 shows the case where each sub-irradiation region 29 is composed of 4×4 pixels, for example. In the writing operation shown in FIG. 19, for example, while the XY stage 105 moves the distance L of eight beam pitches, four different pixels 36 in the same sub-irradiation region 29 are written (exposed) by applying four shots of the multiple beams 20 at a shot cycle T with sequentially shifting the irradiation position (pixel 36) by the sub deflector 209. In order that the relative position between the irradiation region 34 and the substrate 101 may not be displaced by the movement of the XY stage 105 while the four pixels 36 are written (exposed), the irradiation region 34 is made to follow the movement of the XY stage 105 by collective deflection of all of the multiple beams 20 by the main deflector 208. In other words, a tracking control is performed. After one tracking cycle is completed, tracking is reset to return to the previous (last) tracking start position. Since writing of the pixels in the first column from the right of each sub-irradiation region 29 has been completed, in the next tracking cycle after resetting the tracking, first, the deflector 209 provides deflection such that the writing position of a beam is adjusted (shifted) to write the second pixel column from the right which has not yet been written in each sub-irradiation region 29, for example. By repeating this operation during performing writing in the stripe region 32, as shown in the lower part of FIG. 4, the position of the irradiation region 34 (34a to 34o) of the multiple beams 20 is sequentially moved (shifted) to perform writing.

For example, when aiming to increase a blur and/or LER, in performing the writing operation along with a writing grid pattern, the position of the writing grid 27 is shifted, for each shot, from the position of the ideal grid 17 by collectively deflecting the multiple beams 20 by the sub deflector 209, by the grid shift amount defined for the writing grid 27 (pixel 36) concerned. In the example of FIG. 19, when writing the pixel 36 in the first row of the first pixel column from the right in each sub-irradiation region 29, the beam irradiation position is shifted by the grid shift amount defined for the writing grid 27 of the pixel concerned, by beam deflection by the sub deflector 209. After completing the shot cycle T, in writing the pixel 36 in the second row, the beam irradiation position is shifted by the grid shift amount defined for the writing grid 27 of the pixel concerned, by beam deflection by the sub deflector 209. Then, after completing the shot cycle T, in writing the pixel 36 in the third row, the beam irradiation position is shifted by the grid shift amount defined for the writing grid 27 of the pixel concerned, by beam deflection by the sub deflector 209. Then, after completing the shot cycle T, in writing the pixel 36 in the fourth row, the beam irradiation position is shifted by the grid shift amount defined for the writing grid 27 of the pixel concerned, by beam deflection by the sub deflector 209. Then, after completing the shot cycle T, in writing the pixel 36 in the first row of the second pixel column from the right in the sub-irradiation region 29, which is shifted by eight beam pitches by tracking resetting, the beam irradiation position is shifted by the grid shift amount defined for the writing grid 27 of the pixel concerned, by beam deflection by the sub deflector 209. Hereafter, the operation is repeated similarly.

For example, when aiming to increase a shift amount of a pattern mean position, in performing the writing operation along with a writing grid pattern, the position of the writing grid 27 during a tracking cycle is shifted from the position of the ideal grid 17 by collectively deflecting the multiple beams 20 by the main deflector 208, by the grid shift amount corresponding to the number of times of tracking, for example.

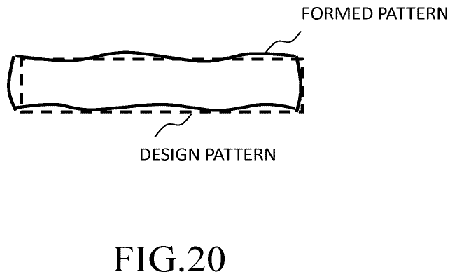

FIG. 20 is an illustration showing an example of a pattern formed by writing according to the first embodiment. As shown in FIG. 20, a figure pattern (solid line) whose edge position is shifted from a design figure pattern (dotted line) can be formed by writing while shifting (offsetting) the position of the writing grid to be matched with performance of a desired previous generation writing apparatus.

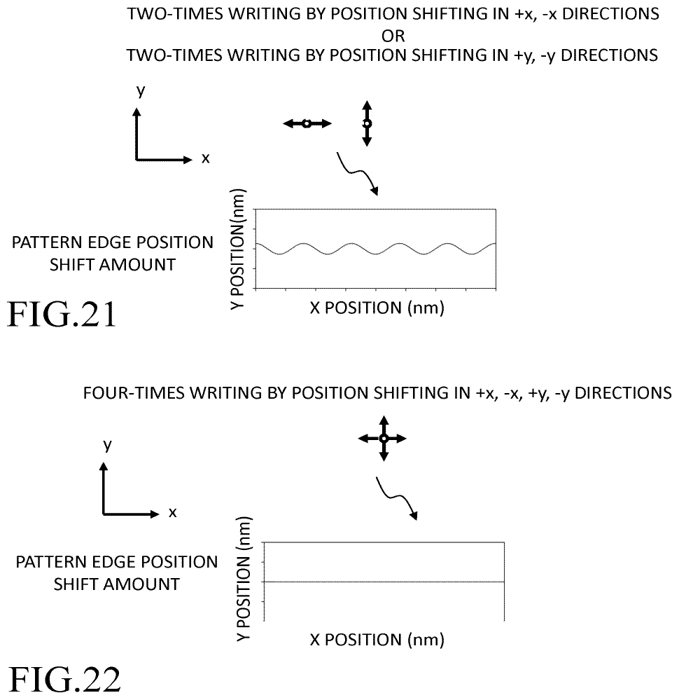

FIG. 21 is an illustration showing an example of a pattern edge shape in the case of performing multiple writing according to the first embodiment. For example, even when a writing grid pattern for LER is used, the size of blurring can be increased while inhibiting an LER increase, by performing grid shifting by two-times multiple writing whose directions are opposite between one and the other writing and whose grid shifting amounts are the same. In other word, positions of at least a portion of a plurality of writing grids are shifted by the same amount in opposite directions between one writing process of the multiple writing processes and another writing process. In the case of FIG. 21, when performing two-times multiple writing while grid shifting with the same grid shift amount in the +x and −x directions, with respect to an x-direction pattern edge (edge itself extending in the y direction), the size of blurring can be increased while inhibiting an LER increase. Furthermore, in the case of FIG. 21, as to the y direction, since the multiple writing is not performed in the opposite direction, the pattern edge is formed wavy and an LER increase is generated.

FIG. 22 is an illustration showing another example of a pattern edge shape in the case of performing multiple writing according to the first embodiment. For example, even when a writing grid pattern for LER is used, the size of blurring can be increased while inhibiting an LER increase, by performing grid shifting by four-times multiple writing, where, in half of the four-times multiple writing, the grid shift directions with respect to the x direction are opposite between one and the other writing and the grid shift amounts are the same, and, in the other half of the four-times multiple writing, the grid shift directions with respect to the y direction are opposite between one and the other writing and the grid shift amounts are the same. In the case of FIG. 22, when performing four-times multiple writing while grid shifting with the same grid shift amount in the +x, −x, +y, and −y directions, the size of blurring can be increased while inhibiting an LER increase, with respect to an x-direction pattern edge (edge itself extending in the y direction) and a y-direction pattern edge (edge itself extending in the x direction). Furthermore, in the case of FIG. 22, since the multiple writing has been performed in the opposite direction with respect also to the y direction, the straight line of the pattern edge is still maintained, and the size of blurring can be increased while inhibiting an LER increase.

As contents to be matched with performance of a previous generation writing apparatus, in addition to the increase in blurring, the increase in LER, and the increase in the shift amount of a pattern mean position, degradation of critical dimension uniformity (CDU) among a plurality of patterns can be mentioned.

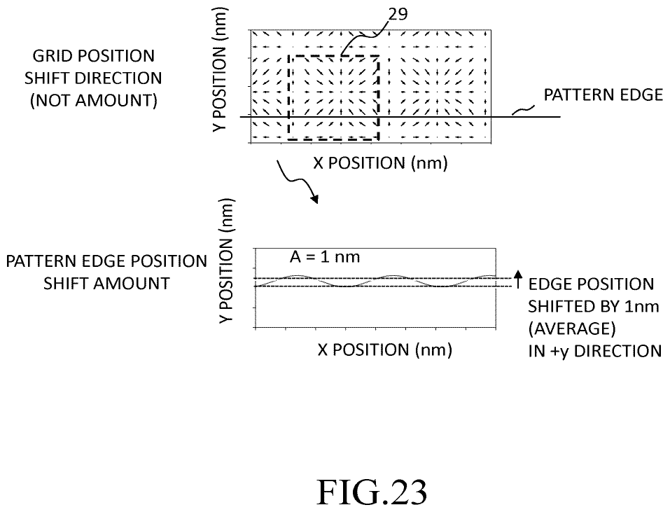

FIG. 23 is an illustration showing an example of a writing grid pattern in the case of degrading critical dimension uniformity among patterns according to the first embodiment. FIG. 23 shows the case where each sub-irradiation region 29 is composed of 8×8 writing grids 27 (or pixels).

In the case of degrading CDU, with respect to a plurality of columns in which the position shift amounts of writing grids 27 in the sub-irradiation region 29, on the surface of the target object 101, surrounded to be a quadrangle by the beam pitch size of the multiple beams 20 are aligned in the y direction, it is set such that the x-direction shift amounts in the same column are the same and the y-direction shift amounts in the same column are different, and sums of vectors each representing a position shift amount in each column are different from each other. Similarly, with respect to a plurality of rows in which the position shift amounts of writing grids 27 in the sub-irradiation region 29 are aligned in the x direction, it is set such that the y-direction shift amounts in the same row are the same and the x-direction shift amounts in the same row are different, and sums of vectors each representing a position shift amount in each row are different from each other. Thereby, it is possible to shift the mean position of a pattern edge by a predetermined amount in a desired direction. In the example of FIG. 23, the mean position of the pattern edge can be shifted by 1 nm in the +y direction. Accordingly, the line widths of a portion of a plurality of patterns can be changed. Consequently, it is possible to degrade CDU.

As described above, according to the first embodiment, it is possible to write, using a high-precision writing apparatus, a pattern of precision obtained by a low-precision writing apparatus, without replacing the hardware. Furthermore, by increasing the total blur by a desired value, it is possible to match the performance of the current generation writing apparatus 100 of high performance to the performance of a previous generation writing apparatus. Furthermore, it is possible to restrict a writing precision by a method other than increase in total blurring.

Embodiments have been explained referring to specific examples described above. However, the present invention is not limited to these specific examples. Although, in the above embodiments, all the grids are shifted from the ideal grid, it is not necessary to shift all the grids from the ideal grid. For example, desired effects described above can also be obtained by shifting ¼ or more of the whole grids. Functions of processing described in each embodiment may be executed by a computer. A program for causing a computer to implement such functions of processing may be stored in a non-transitory tangible computer-readable storage medium such as a magnetic disk drive.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any multi-charged particle beam writing method, multi-charged particle beam writing apparatus, and program (or non-transitory computer-readable storage medium storing a program) that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-charged particle beam writing method comprising:
setting, in a writing region on a target object, a plurality of writing grids in which relative positions of at least a portion of the plurality of writing grids are shifted from a plurality of ideal grids arranged at an even pitch in a gridded shape; and
writing, using multiple beams, a pattern on the target object such that the plurality of writing grids in which the relative positions of the at least the portion of the plurality of writing grids are shifted are irradiated.

2. The method according to claim 1, further comprising:
deflecting, for each shot, the multiple beams, based on a position shift amount of the at least the portion of the plurality of writing grids.

3. The method according to claim 1, wherein
positions of the plurality of writing grids are shifted at a predetermined pitch from the plurality of ideal grids.

4. The method according to claim 1, further comprising:
rasterizing, in the plurality of ideal grids, pattern data to be written, wherein
the plurality of writing grids in which the relative positions of the at least the portion of the plurality of writing grids are shifted are irradiated with a beam of a dose for each of the plurality of ideal grids, the dose being based on the pattern data rasterized in the plurality of ideal grids.

5. The method according to claim 1, wherein
the plurality of writing grids are set such that a sum of vectors is to be a fixed value, each of the vectors representing a position shift amount of each of the plurality of writing grids in each of a plurality of sub-regions obtained by dividing a region, on a surface of the target object, surrounded to be a quadrangle by a beam pitch size of the multiple beams.

6. The method according to claim 1, wherein
the plurality of writing grids are set such that a sum of vectors in each column and a sum of vectors in each row are individually to be fixed values, each of the vectors representing a position shift amount of each of the plurality of writing grids in a region, on a surface of the target object, surrounded to be a quadrangle by a beam pitch size of the multiple beams.

7. A multi-charged particle beam writing apparatus comprising:
a writing grid setting circuit configured to set, in a writing region on a target object, a plurality of writing grids in which relative positions of at least a portion of the plurality of writing grids are shifted from a plurality of ideal grids arranged at an even pitch in a gridded shape; and
a writing mechanism configured to write, using multiple beams, a pattern on the target object such that the plurality of writing grids in which the relative positions of the at least the portion of the plurality of writing grids are shifted are irradiated.

8. A non-transitory computer-readable storage medium storing a program for causing a computer to execute processing comprising:
setting, in a writing region on a target object, a plurality of writing grids in which relative positions of at least a portion of the plurality of writing grids are shifted from a plurality of ideal grids arranged at an even pitch in a gridded shape;
storing, in a storage device, the plurality of writing grids having been set; and
reading the plurality of writing grids from the storage device, and making a writing mechanism write, using multiple beams, a pattern on the target object such that the plurality of writing grids in which the relative positions of the at least the portion of the plurality of writing grids are shifted are irradiated.

9. The method according to claim 1, wherein
multiple writing processes are performed with the multiple beams on the target object, and
positions of the at least the portion of the plurality of writing grids are shifted by a same amount in opposite directions between one writing process of the multiple writing processes and another writing process.

10. The method according to claim 1, wherein
a position shift amount of a writing grid is changed depending on a shift amount in an average position of at least one of a blur, line edge roughness, and a pattern obtained with a previous generation writing device.

11. The method according to claim 1, wherein
a plurality of writing grids in which relative positions of at least a portion of the plurality of writing grids are shifted are set by providing a position shift amount to at least a portion of the plurality of ideal grids.
